(19) United States
(12) Patent Application Publication
(10) Pub. No.: US 2007/0268016 A1
(43) Pub. Date: Nov. 22, 2007

(54) Apparatus for detecting magnetic signals and signals of electric tunneling

(76) Inventors: Cheng-Chung Chi, Hsinchu (TW); Yang-Chung Liao, Hsinchu (TW); Ming-Jye Wang, Taipei (TW)

Correspondence Address: LOWE HAUPTMAN HAM & BERNER, LLP, 1700 DIAGONAL ROAD, SUITE 300, ALEXANDRIA, VA, 22314, US

(21) Appl. No.: 11/434,107

(22) Filed: May 16, 2006

(51) Int. Cl. G01R 33/02

(52) U.S. Cl. 324/248

(57) ABSTRACT

A scanning probe microscope comprises a magnetic sensor and a sensor of electric tunneling current. The miscroscope integrates both the advantages of scanning SQUID microscope (SSM), and scanning tunneling microscope (STM), into a single instrument by applying a high-permeability metallic tip such as a permalloy tip, a pick-up coil and a transformer coupling the tip and the SQUID chip together. The local magnetic field of the test sample induces a substantial magnetization in the probing tip of high permeability. Through the pick-up coil inductively coupled to the tip, the magnetic signal of the induced moment is transferred to the SQUID chip via the transformer to achieve the best flux transferring condition. The metallic tip has the capability of sensing tunneling current and thus this instrument can also retain the capabilities of the STM, such as topography, current images and mappings of local density of state. This microscope can be used to observe both the magnetic signal and the electric tunneling signal simultaneously and can manipulate the tip by using either the magnetic signal or the electric tunneling signal as the feedback control.

### BACKGROUND OF THE INVENTION

1. Field of the Invention

The present invention relates to an apparatus for building up a scanning probe microscope with the capability of detecting delicate electronic and magnetic signal. It combines the advantages of two microscopes—Scanning SQUID Microscope (SSM) and Scanning Tunneling Microscope (STM). The SSM is capable of measuring a delicate variation of magnetic field, and the STM can resolve tunneling currents in atomic scale.

2. Description of the Prior Art

The current technology of scanning probe microscope (SPM), which can observe phenomena in micro world through scanning probe tip over sample, is developed from scanning tunneling microscope (STM) first disclosed in Phys. Rev. Lett. 49, 57 (1982) by G. Binnig et al. The main components of STM are tunneling tip, scanning module for controlling the relative position between tip and sample, and detecting and processing module for measuring the related electric signal and image of signal mapping. The tunneling current between tip and sample is a function of exponential decay with the exponent mostly depending on the local density of state (LDOS) of sample surface, and the perpendicular separation between tip and sample surface. Typically the tunneling current flows between tip and sample around the separation of 10 A (1 nm) and the tunnel distance could be stably controlled to within 0.2 A. The dramatic drop of tunneling current with the separation gives rise to the tunneling limited in a local area and thus enables the microscope to portray the surface morphology in atomic resolution. In detecting spins in sample, there is a variation of STM called spin-polarized scanning tunneling microscope (SP-STM) pioneered by W. Wiesendanger et al. SP-STM uses the spin-valve effect between the magnetic tip and sample to detect the local magnetization through the tunneling rate, which is high when spins of ferromagnetic tip and sample are parallel with each other and becomes low when they are antiparallel. Although this technique may have the atomic-scale resolution, the application of this instrument is limited in the detection of magnetization with the imbalance of Fermi level. Considering the force between the probe and sample, Binnig and other researchers developed several SPMs including atomic force microscope (AFM), magnetic force microscope (MFM), etc. Based on the same scanning methodology, a research group at IBM has developed another SPM called scanning superconducting quantum interference device (SQUID) microscope (SSM) disclosed in Appl. Phys. Lett. 66, 1138 (1995) by J. R. Kirtley et al., which has a much better magnetic field sensitivity but worse spatial resolution (about μm) than a typical MFM. The success of SSM depends on the high magnetic flux sensitivity of SQUID and the transfer mechanism of the magnetic flux to the SQUID chip. The advantage of SSM is its high magnetic flux (magnetic field integrated over the sensing area) sensitivity in the range of 10⁻⁴˜10⁻⁶φ₀ Hz^{-1/2} , and its disadvantage is the requirement of a cryogenic environment and modest spatial resolution.

MFM is a common tool in the field of detecting microscopic magnetism. This instrument detects the magnetic force between the ferromagnetic tip on the cantilever and sample, where the deflection of the cantilever is used to estimate the local magnetic moment. The magnetic and spatial resolutions of conventional MFM is around 10⁴ μ_{B} and 100 nm respectively. On the other hand, a magnetic resonance force microscope (MRFM) was proposed to resolve the signal of single spin and recently the achievement was published by D. Rugar et al. in Nature 430, 329 (2004). MRFM employs the resonance between the Larmor frequency of spin precession and the vibration frequency of cantilever to enhance the deflection of cantilever. However, this characteristics of MRFM requires its applications to be conducted in certain environments, such as, low enough temperature to avoid thermal-magnetic noise and strong external magnetic field to ensure the alignment of all spins. Owing to the requirement of spin precession, MRFM cannot be used to detect the magnetic field generated by current.

The magnetic flux sensitivity of a low temperature SQUID is typically better than 10⁻⁶φ₀ Hz^{-1/2} , but poor coupling efficiency of magnetic flux may degrade the sensitivity of SSM by more than one order of magnitude. Using a direct magnetic coupling scheme, a larger SQUID pick-loop area will result in higher magnetic field sensitivity. Unfortunately, the resolvable spatial feature size is proportional to the loop size. An optimal design of SSM is a compromise of magnetic field sensitivity and spatial resolution. How to keep the magnetic sensitivity and to improve the spatial resolution at the same time is a challenge. One of the solutions was disclosed in U.S. Pat. No. 6,211,673 B1 where described a method to guide the magnetic flux generated by sample to the SQUID chip via a soft ferromagnetic filament directly pointing to the SQUID chip. The soft ferromagnetic filament embedded in the tip of a typical AEM cantilever conducts the magnetic signal on sample surface to the SQUID chip without sacrificing the area of SQUID pick-up loop and thus maintains high magnetic sensitivity. Meanwhile, sharpening the filament to about the order of 10 nm can enable a good spatial resolution in the microscope. The employment of sharp high-permeability flux guide therefore provides a possible solution to improve both the magnetic sensitivity and the spatial resolution in an instrument.

U.S. Pat. No. 4,677,512 discloses a magnetic reproducing apparatus including a magnetic guide, and two coils, one for writing magnetic signal and the other for the inductor in the tuning circuit of detecting magnetic signal. The magnetic guide induces the magnetization of signal to be recorded on sample via applying a current in writing coil wound on the guide. The variation of magnetic field changes the permeability of the guide where the second coil disposed in its proximity and thus the inductance of the coil is altered. To detect the magnetic signal in sample, the frequency shift in the RLC tuning circuit is measured. These two coils function as the component inducing magnetization in the magnetic guide and an inductor in the detecting circuit respectively.

To achieve an instrument with both of high magnetic sensitivity and high spatial resolution is still a demanding task. SP-STM and MRFM seem like good solutions, but their application is limited in detecting the magnetic signal generated by spins. SSM do not have this limitation however until now it is hard to solve the dilemma of magnetic sensitivity and spatial resolution. Though U.S. Pat. No. 6,211,673 B1 proposed a possible way to tackle the problem, the arrangement of related devices is a bit of impracticability. An innovation to couple the magnetic flux to SQUID chip is needed.

### SUMMARY OF THE INVENTION

In accordance with this invention, an apparatus for detecting signals of electric tunneling and magnetic signal is disclosed, it comprises a tip, a magnetic sensitive device, a coil transferring the magnetic flux of the tip to the magnetic sensitive device, a magnetic shield, and a module for the electrical and actuated control. The present invention is to simultaneously improve the magnetic sensitivity and the spatial resolution of an apparatus while giving more degrees of freedom to dispose the magnetic sensitive device. More specifically this invention is to improve the spatial resolution of an SSM. Another embodiment of this invention is an SPM capable of mapping signals of electric tunneling and magnetic signals simultaneously.

To enhance the spatial resolution of an apparatus detecting magnetic signals, a high-permeability tip is disposed to sense the magnetic field generated by sample. The spatial resolution is thus determined by the diameter of vertex of the tip. In consideration of without influencing the magnetic state of sample, the high-permeability tip should have a residual moment and a coercive force as small as possible. Using the technology of microelectromechanical systems (MEMS) can sharpen the tip with a high aspect ratio to a diameter around 10 nm. A pick-up coil inductively coupling with the thick stem of the tip transfers the magnetic flux to a magnetic sensitive device measuring the magnetic signals. There is no restriction in the position of the magnetic sensitive device in this arrangement. In consideration of impedances matching, a transformer can be designed to reconcile the difference between the pick-up coil and the magnetic sensitive device. The employment of superconducting pick-up coil and transformer can further improve the flux coupling efficiency. In the present invention, the magnetic sensitive device is a device sensitive to magnetic field, magnetic flux and magnetic force. There are several variations in the magnetic sensitive device, which comprise at least a magnetic sensor such as Hall sensor, giant magnetoresistance (GMR) device, tunnel magnetoresistance (TMR) device and SQUID. The preferred magnetic sensor is SQUID. In order to suppress the magnetic noise, a magnetic shield comprising such as u-metal or superconductor is applied to cover the pick-up coil and the high-permeability tip except the apex. Several slits on the shield in parallel with the axis of the tip are constructed to reduce the interference of eddy currents or induced supercurrents. Typically an SPM has a module of actuation control for the function of scanning. The module of the electric and actuated control in the present invention is for this purpose. In this sense, the apparatus described here is an SPM capable of detecting magnetic signal with improved spatial resolution. More specifically the apparatus just described is a SSM with an improved spatial resolution.

In the case of high-permeability metallic tip, the apparatus described in this invention is capable of detecting signals of electric tunneling and magnetic signals simultaneously. The module of electric and actuated control monitors the tunneling currents and controls the separation between the tip and sample in the way well known to a person skilled in the art of STM. Operating in the mode of constant tunneling current usually allows the separation between the tip and sample stably keep in the order of magnitude of angstrom. This can enhance the accuracy and the sensitivity of magnetic signal further.

The application of the present invention is not limited to an SPM. A module of coupling magnetic signals to a magnetic sensitive device, comprising a tip, a magnetic sensitive device, a coil transferring the magnetic flux of the tip to the magnetic sensitive device and a magnetic shield etc., can be applied to an apparatus of detecting magnetic signal. The respective components of this module are similar to that described previously. This module can enable an apparatus to have more degrees of freedom to dispose the magnetic sensitive device and to enhance spatial resolution without losing magnetic sensitivity.

Unlike the U.S. Pat. No. 6,211,673 B1 that the magnetic-field device is restricted to be disposed on an AFM cantilever, this invention provides a new method to couple the magnetic flux. This method has several benefits than the previous one, which are an enhanced flux coupling that can be achieved by increasing the winding turns of the coil, by winding coils directly on the other end of the tip or the magnetic-flux guide, and a flexible site to place the SQUID chip. These two advantages can significantly improve the performance in scanning magnetic signal. For example, the enhanced flux coupling can increase the magnetic sensitivity and the flexibility to place the SQUID chip allows people to operate the chip with the less trade-off. In the case of metallic tip, this tip has the capability of STM tip as well. Therefore, this invention can fulfill the function of detecting delicate electronic and magnetic signal in a single instrument.

A more complete understanding of these and other features and advantages of the prevent invention will become apparent from a careful consideration of the following detailed description of certain embodiments illustrated in the accompanying drawings.

### BRIEF DESCRIPTION OF THE DRAWINGS

FIG. 1 is a view showing the embodiment of present invention;

FIG. 2 is a drawing showing the function of present invention.

### DETAILED DESCRIPTION OF THE PREFERRED EMBODIMENTS

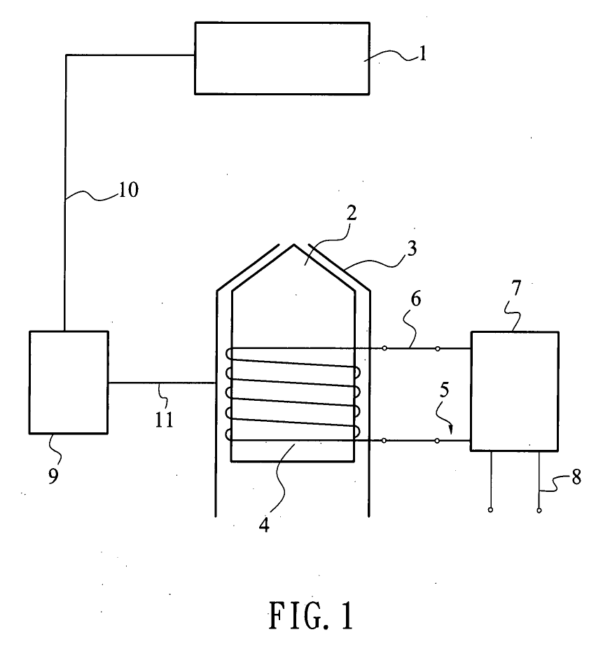

FIG. 1 schematically illustrates the embodiment of the present invention. A high-permeability material with tiny residual moment is used to fabricate the tip 2. The preferred material is Permalloy or u-metal that are the alloy of Nicole, Iron and some other transition metals. Their bulk permeability has a typical value larger than 10⁴. The magnetic field from sample 1 induces magnetization in the tip 2. The large permeability of the tip 2 can magnify the magnetic signal. In order to reduce the magnetic noise and increase the spatial resolution, the magnetic shield 3 covers the tip 2 and the pick-up coil 4 except the very apex of the tip. The shield can be made of a high-permeability material or a superconductor. There are several slits formed on the shield to suppress eddy currents or supercurrents. Through the pick-up coil 4 inductively coupled to the tip 2 or directly wound on the tip, the magnetic signal is transferred to the magnetic sensitive device 7 in the form of magnetic flux via the electrical connections 5 of twisted-pair wires or coaxial cables. In the magnetic sensitive device 7, the signal input lines 6 could be the input of a flux transformer and the output of this transformer is coupled with a magnetic sensitive device and/or a magnetic sensor. This transformer can bridge the difference of impedance between the pick-up coil and the magnetic sensitive device and/or the magnetic sensor. The magnetic signal is then read out from the signal output lines 8 that are connected to the magnetic sensitive device and/or the magnetic sensor. The tip 2 of permalloy orp-metal is a tunneling tip as well. In the FIG. 1 the actuation control and measurement of tunneling current is accomplished by the module 9, the link 10 between the sample 1 and the module 9, and the link 11 between the tip 2 and the module 9. The module 9 comprises units for measuring electric signal and applying bias voltage, and actuation and actuation control of the relative moment between the sample and the tip. For people skilled in the art of SPM, the detailed constructions of the module 9, the link 10 and 11 are well known to them. In this sense, the present invention can be employed to fabricate an SPM capable of detecting signals of electric tunneling and magnetic signal simultaneously.

To increase the spatial resolution, the tip 2 can be sharpened by the technology of MEMS. The tip at first is electrochemical etched in a solution, such as acid or alkali solution. After the electrochemical etching process, the aspect ratio of the very apex is not high enough to the application of scanning for a magnetic distribution in high spatial resolution. One of common tools in MEMS, the focus ion beam (FIB), can be used to mill the apex of the tip. It is possible in current technology that the apex can reach in a diameter around 10 nm with an aspect ratio about 100. The employment of this tip can significantly enhance the spatial resolution in the scanning of magnetic signal.

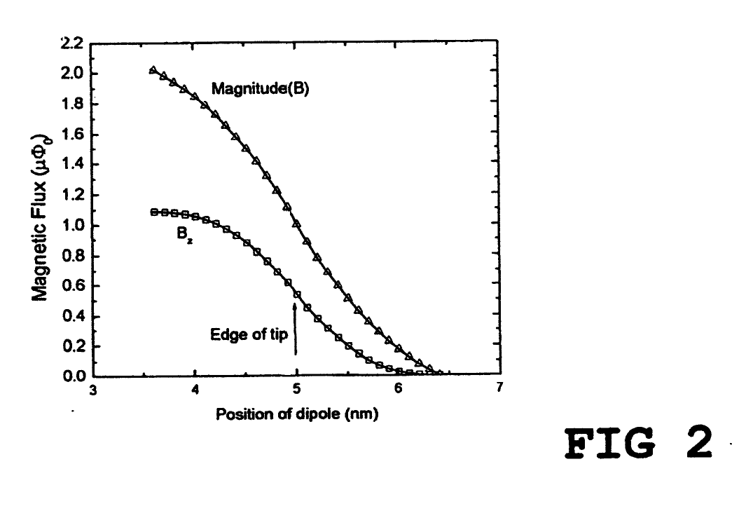

The preferred magnetic sensitive device 7 comprises a SQUID chip and a superconductor transformer. A low temperature SQUID has a magnetic flux sensitivity better than 10⁻φ₀ Hz^{-1/2}. The SQUID chip can be designed to possess an inductance in the order of magnitude of 100 nH. Through the superconducting pick-up coil wound on the sharpen high-permeability tip, the magnetic signal is input into the superconductor transformer. For a 10-turns coil on a typical tip (diameter around 0.5 mm), the inductance is in the order of magnitude of 100 nH. The impedance mismatch between the SQUID chip and the pick-up coil can be reconciled by such superconducting transformer that the loss of magnetic signal input into the SQUID is greatly reduced. The minimum detectable magnetic field is defined as the average field at the tip providing a magnetic flux to the SQUID higher than its noise level. The magnetic flux at the SQUID is Φ=Bₜᵢₚ×A×M×C, where in Bₜᵢₚ is the average field at the tip, the effective area (A) of the tip is π (5 nm)², the flux magnification factor (M) of the tip is conservatively assumed to be 1000, and the flux coupling coefficient (C) between tip and SQUID is 0.5. This estimation gives Φ a value of 3.9×10⁻¹⁰ Bₜᵢₚ (G-cm²). Suppose that the noise of the SQUID chip is 2×10⁻⁶ Φ₀˜4×10⁻¹³ G-cm², the estimated value of the minimum detectable field should be about 1 mG. This field sensitivity increases quadratically with the increasing tip diameter. To estimate the spatial resolution, a magnetic dipole of single Bohr magneton μ_{Bo} is located at position of X=Xₒ relative to the center of tip with 1 nm separation in the z-direction. For simplicity, the effect of magnetic field distortion due to the existence of permalloy tip is neglected. In FIG. 2, the open square is calculated by counting the magnetic field normal to the surface of tip bottom and the open triangle integrates the magnitude of field at the surface. The total magnetic flux of the dipole is under-estimated at the position out of the tip edge because we do not consider the contribution of magnetic flux at the side-wall of the tip. As shown in FIG. 2, the magnetic flux detected by the SQUID chip is above its resolution limit. This result shows that the spatial resolution is similar to the diameter of the tip (here is 10 nm) and the capability to detect a single Bohr magneton is achievable.

There are variations of the apparatus described in FIG. 1. Without measuring and controlling the tunneling signal, the instrument can still measure the magnetic distribution as well. For example, it is an SSM in the situation of employing SQUID chip as the magnetic sensitive device. The method of coupling magnetic flux by using the high-premeability tip, the pick-up coil and the magnetic sensitive device can also be applied to any apparatus detecting magnetic signal.

As the present invention has been shown and described with reference to preferred embodiments thereof, those skilled in the art will recognize that the above and other changes may be made therein without departing from the spirit and scope of this invention.

1. An apparatus for detecting magnetic signals and signals of electric tunneling, simultaneously, said apparatus comprising:
a tip for conducting magnetic signals sensed by the apex of said tip, and serving as an electrode in measuring signals of electric tunneling;
a magnetic shield for screening a magnetic field except at the very apex of said tip;
a magnetic sensitive device and a pick-up coil inductively coupling the tip and the magnetic sensitive device for transferring the signals of magnetic flux generated by said tip to the magnetic sensitive device; and wherein the magnetic sensitive device measures the magnetic signals from said pick-up coil; and
a module installed between said pick-up tip and a sample, for measuring signals of electric tunneling between said tip and the sample, and applying a bias voltage between the tip and the sample for actuation control of the tip or the sample.

2. The apparatus as claimed in claim 1, wherein said tip is made of a high-permeability electric conductor.

3. The apparatus as claimed in claim 1, wherein said tip is made of a soft ferromagnetic electric conductor.

4. The apparatus as claimed in claim 1, wherein said magnetic shield is made of a high-permeability metal or superconductor material.

5. The apparatus as claimed in claim 1, wherein said magnetic shield is a superconductor film coated on said tip.

6. The apparatus as claimed in claim 1, wherein said coil is directly wound on said tip.

7. The apparatus as claimed in claim 1, wherein said coil is made of superconductor material.

8. The apparatus as claimed in claim 1, wherein said magnetic sensitive device comprises a coil or a set of coils that transfer magnetic signals to a magnetic sensor.

9. The apparatus as claimed in claim 9, wherein said coil or a set of coils is made of a superconductor material.

10. The apparatus as claimed in claim 1, wherein said magnetic sensitive device comprises a SQUID.

11. An apparatus for detecting magnetic signals, comprising:
a tip for conducting magnetic signals sensed by the apex of said tip;
a magnetic shield for screening a magnetic field except at the very apex of said tip;
a magnetic sensitive device and a pick-up coil inductively coupling the tip and the magnetic sensitive device for transferring the signals of magnetic flux generated by said tip to a magnetic sensitive device; and wherein
the magnetic sensitive device measures the magnetic signals from said pick-up coil.

12. The apparatus as claimed in claim 11 wherein said tip is made of a high-permeability material.

13. The apparatus as claimed in claim 11, wherein said tip is made of a soft ferromagnetic material.

14. The apparatus as claimed in claim 11, wherein the magnetic shield is made of a high-permeability metal or superconductor material.

15. The apparatus as claimed in claim 11, wherein the magnetic shield is a superconductor film coated on said tip.

16. The apparatus as claimed in claim 11, wherein the coil is directly wound on said tip.

17. The apparatus as claimed in claim 11, wherein the coil is made of superconductor material.

18. The apparatus as claimed in claim 11, wherein the magnetic sensitive device comprises a coil or a set of coils that transfer magnetic signals to a magnetic sensor.

19. The apparatus as claimed in claim 18, wherein said coil or a set of coils is made of a superconductor material.

20. The apparatus as claimed in claim 11, wherein said magnetic sensitive device comprises a SQUID.
